(19) United States
(12) Patent Application Publication
(10) Pub. No.: US 2012/0212923 A1
(43) Pub. Date: Aug. 23, 2012

(54) DISPLAY UNIT HAVING SELF-LOCKING STRUCTURE TO FIX DISPLAY THEREOF

(75) Inventors: KE-HUI PENG, Shenzhen City (CN); XUE-DONG TANG, Shenzhen City (CN); LI-NI LIANG, Shenzhen City (CN); REN-WEN WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/049,824

(22) Filed: Mar. 16, 2011

(30) Foreign Application Priority Data
Feb. 18, 2011 (CN) 201110043534.9

(51) Int. Cl. H05K 7/02

(52) U.S. Cl. 361/807

(57) ABSTRACT

An exemplary display unit includes a lower cover, an upper cover, and a display sandwiched between the upper cover and the lower cover. The lower cover includes a lower plate for supporting the display thereon, a first clip to fix the display on the lower plate, a bracket, and a rib. The upper cover includes an upper plate adjoined to the lower plate to cover the display, two fins pressing against the first clip, a second clip secured to the bracket, and a beam engaged with the rib.

### BACKGROUND

1. Technical Field

The present disclosure relates to display units, and more particularly, to a display unit which can be conveniently assembled.

2. Description of Related Art

Display systems play an important role in people's daily lives, showing images and text for all kinds of purposes. A display system typically includes a display, a front enclosure and a back enclosure. The display is assembled between the front enclosure and the back enclosure. However, in most conventional display systems, the assembly of the display to the front enclosure and the back enclosure is achieved by using separate fasteners (such as screws or bolts, and has to be completed with the help of tools such as a screwdriver. Therefore, the display system cannot be quickly and conveniently assembled.

What is needed, therefore, is a display unit which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows part of an assembled display unit in accordance with an embodiment of the present disclosure, wherein a part of the display unit is cut away along a line to expose a cross section of the display unit.

FIG. 2 is an exploded view of the display unit of FIG. 1.

FIG. 3 is an exploded view of part of the display unit of the present disclosure when the display unit is inverted, wherein another part of the display unit is cut away along another line different from that of FIG. 1 to expose another cross section of the display unit.

FIG. 4 is a plan view of the cross section of the display unit of FIG. 1.

### DETAILED DESCRIPTION

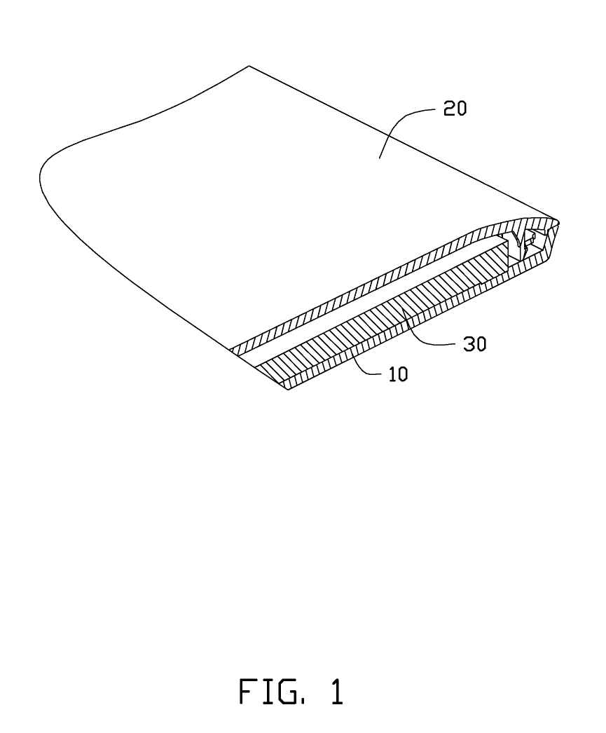

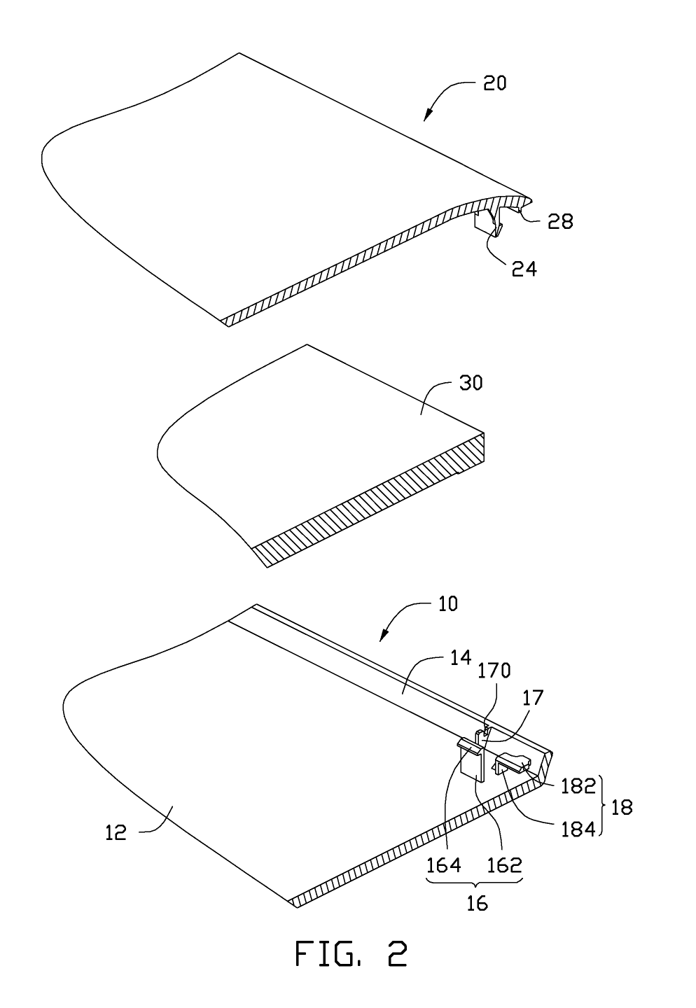

Referring to FIGS. 1-2, a display unit in accordance with an embodiment of the present disclosure is shown. The display unit includes an upper cover 20, a lower cover 10, and a display 30 sandwiched between the upper cover 20 and the lower cover 10.

The display 30 has a rectangular configuration. The display 30 may be an LCD (Liquid Crystal Display), an OLED (Organic Light Emitting Diode) display or another suitable display.

The lower cover 10 includes a rectangular lower plate 12, a flange 14 extending upwardly and slantwise from a side of the lower plate 12, a first clip 16 protruding upwardly from a top face of the lower plate 12, a bracket 18 connecting the lower plate 12 with the flange 14, and a rib 17 extending upwardly from the flange 14. The lower plate 12 has a size larger than that of the display 30, so that the display 30 can be substantially received in the lower cover 10. The flange 14 is inclined in a manner that an included angle between the flange 14 and the lower plate 12 is larger than 90 degrees and less than 180 degrees. Preferably, the included angle between the flange 14 and the lower plate 12 is about 120 degrees. The flange 14 has a width far less than a length thereof. The first clip 16 includes a first stem 162 perpendicular to the lower plate 12, and a first hook 164 protruding horizontally from a top end of the first stem 162. The first stem 162 is elastically deformable, and has a length larger than a thickness of the display 30. The first stem 162 can press against a lateral face of the display 30 to position the display 30 on the lower plate 12. The first hook 164 is oriented towards the display 30. The first hook 164 can press a part of a top face of the display 30 near the lateral face thereof downwardly towards the lower plate 12 so as to fix the display 30 on the lower plate 12.

The rib 17 is perpendicular to the flange 14 and the lower plate 12. The rib 17 has a trapezoidal configuration, with a top face thereof being coplanar with that of the flange 14. A rectangular groove 170 is defined in the top face of the rib 17. The bracket 18 is located neighboring the first clip 16. The bracket 18 includes a connecting portion 184 extending upwardly from the top face of the lower plate 12, and a locking portion 182 extending horizontally from the flange 14 and connected to the connecting portion 184. The connecting portion 184 has a length less than that of the first stem 162. The connecting portion 184 is perpendicular to the first stem 162 and the locking portion 182, and parallel to the rib 17. The locking portion 182 is parallel to the lower plate 12.

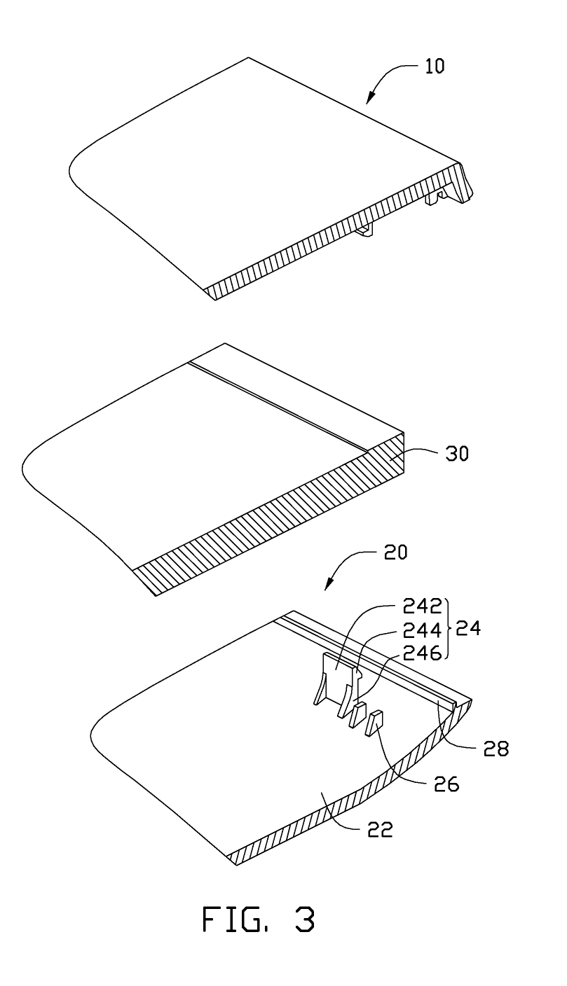

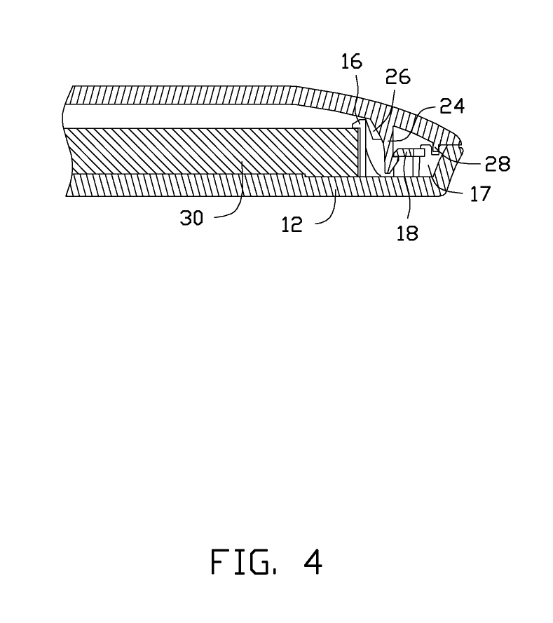

Also referring to FIGS. 3-4, the upper cover 20 includes an upper plate 22, a second clip 24 extending downwardly from a bottom face of the upper plate 22, a pair of fins 26 formed downwardly from the bottom face of the upper plate 22, and a beam 28 protruding downwardly from the bottom face of the upper plate 22. The upper plate 22 is a flat rectangle, with an end curved downwardly towards the flange 14 of the lower cover 10. The curved end of the upper plate 22 contacts the flange 14 to form a chamber (not labeled) between the lower cover 10 and the upper cover 20, the chamber receiving the display 30 therein. The second clip 24 includes a second stem 242 connected to the upper plate 22, a second hook 244 protruding horizontally from a bottom end of the second stem 22, and a pair of reinforcing tabs 246 connecting the second stem 242 to the upper plate 22. The second stem 242 is perpendicular to the lower plate 12, and parallel to the first stem 162. The second hook 244 is oriented in a direction remote from the display 30 and opposite to that of the first hook 164. The second hook 244 is buckled with a bottom face of the locking portion 182 of the bracket 18, to fix the upper cover 20 to the lower cover 10 (shown in FIG. 4). The reinforcing tabs 246 are formed on the second stem 242 opposite to the second hook 242. Each reinforcing tab 246 has a triangular configuration to increase strength of the second clip 24. The pair of fins 26 are located adjacent to the second clip 24 and parallel to the reinforcing tabs 246. Each fin 26 has a trapezoid shape with an inclined surface.

The inclined surfaces of the fins 26 only contact the first hook 164 at an edge of the first hook 164, to produce an inclined pressure applied to the first hook 164. The inclined pressure can be divided into two component forces operating along two perpendicular directions. One of the component forces is oriented horizontally to press the first clip 16 against the display 30 in a horizontal direction towards a middle of the display 30. The other component force is oriented vertically to press the first clip 16 against the display 30 downwardly towards the lower plate 12. Thus, the fin 26 urges the first clip 16, which elastically deforms to press against the display 30. The beam 28 extends along the curved end of the upper plate 22 from one side of the upper cover 20 to an opposite side of the upper cover 20. The beam 28 is fittingly retained into the groove 170 of the rib 17 of the lower cover 10 to position the upper cover 20 relative to the lower cover 10.

The first clip 16 formed on the lower cover 10 can conveniently fix the display 30 on the lower cover 10 without the need for separate fasteners (such as screws or bolts) and without the need for tools, whereby rapid assembly of the display unit can be achieved. Furthermore, the first clip 16 does not occupy too much space between the lower cover 10 and the upper cover 20; therefore, the display unit can be made thin enough to meet critical space requirements.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A display unit comprising:
a lower cover comprising a lower plate, and a first clip extending upwardly from the lower plate;
a display disposed on the lower plate and locked by the first clip; and
an upper cover comprising an upper plate covering the display and a fin extending downwardly from the upper plate, the fin pressing the first clip such that the first clip is elastically deformed towards the display and locks the display in position.

2. The display unit of claim 1, wherein the first clip comprises a first stem perpendicular to the lower plate and a first hook protruding from a top of the first stem.

3. The display unit of claim 2, wherein the first stem abuts against a lateral side of the display and the first hook abuts against a top face of the display.

4. The display unit of claim 2, wherein the fin has an inclined surface in contact with an edge of the first hook to press the first clip against the display.

5. The display unit of claim 4, wherein the pressure applied by the fin to the edge of the first hook comprises a first component force oriented horizontally and urging the first hook towards a middle of the display and a second component force oriented vertically and urging the first hook downwardly.

6. The display unit of claim 2, wherein the lower cover comprises a flange extending slantwise and upwardly from an end of the lower plate.

7. The display unit of claim 6, wherein the upper plate of the upper cover has an end curved downwardly to contact the flange of the lower cover.

8. The display unit of claim 6, wherein the lower cover comprises a bracket connecting the lower plate with the flange.

9. The display unit of claim 8, wherein the upper cover comprises a second clip extending downwardly from the upper plate, the second clip being locked with the bracket.

10. The display unit of claim 9, wherein the bracket comprises a connecting portion extending upwardly from the lower plate and a locking portion extending horizontally from the flange and connected with the connecting portion.

11. The display unit of claim 10, wherein the connecting portion is perpendicular to both the first stem and the locking portion.

12. The display unit of claim 10, wherein the second clip comprises a second stem perpendicular to the lower plate and a second hook protruding from a bottom of the second stem, the second hook pressing against a bottom of the locking portion.

13. The display unit of claim 12, wherein the second hook is oriented towards a direction opposite to that in which the first hook is oriented.

14. The display unit of claim 12, wherein the second clip comprises a pair of reinforcing tabs connecting the second stem with the upper plate, the reinforcing tabs being parallel to the fin.

15. The display unit of claim 6, wherein the lower cover comprises a rib extending upwardly from the flange, the rib defining a groove in a top thereof.

16. The display unit of claim 15, wherein the rib is perpendicular to both the lower plate and the first stem.

17. The display unit of claim 15, wherein the upper cover comprises a beam extending downwardly from the upper plate, the beam being fittingly received in the groove of the rib.

18. A display unit comprising:
a lower cover comprising a lower plate and an elastically deformable first clip extending upwardly from the lower plate;
a display placed on the lower plate and fixed by the first clip; and
an upper cover comprising an upper plate covering the display and a fin extending downwardly from the upper plate;
wherein the fin has an inclined surface pressing against the first clip and applying a first component force and a second component force to the first clip, the first component force urging the first clip to press the display in a direction parallel to the lower plate and the second component force urging the first clip to press the display in a direction perpendicular to the lower plate.

19. The display unit of claim 18, wherein the upper cover comprises a second clip extending downwardly from the upper plate, and the lower cover comprises a bracket extending upwardly from the upper plate, the second clip being locked with the bracket.

20. The display unit of claim 18, wherein the first clip comprises a first stem connecting the lower plate and a first hook extending horizontally from the first stem, and the second clip comprising a second stem connecting the upper plate and a second hook extending horizontally from the second stem, the first hook being oriented towards a direction opposite to that the second hook is oriented towards.
